(19) United States
(12) Patent Application Publication
(10) Pub. No.: US 2025/0370034 A1
(43) Pub. Date: Dec. 4, 2025

(54) AUTOMATED ELECTRICAL PROBING SYSTEM FOR PACKAGED MICROELECTRONICS

(71) Applicant: Chiplytics Inc., Seattle, WA (US)

(72) Inventors: Steven Dourmashkin, Seattle, WA (US); Matthew Skeels, Austin, TX (US); Tom Mikolyuk, Seattle, WA (US); Connor Dempsey, Seattle, WA (US)

(21) Appl. No.: 19/228,239

(22) Filed: Jun. 4, 2025

Related U.S. Application Data
(60) Provisional application No. 63/655,933, filed on Jun. 4, 2024.

(51) Int. Cl. G01R 31/28; G01R 1/073

(52) U.S. Cl. CPC G01R 31/2887; G01R 1/07364; G01R 31/2834; G01R 31/2896

(57) ABSTRACT

Disclosed is an automated electrical probing system for testing a plurality of microelectronic devices. The automated electrical probing system includes a pick-and-place robot configured to move a device under test (DUT) in three-dimensional space and rotate it about a vertical axis. A robot end effector holds and releases the DUT, while a robot-mounted camera detects its position and orientation using computer vision. The DUT is retrieved from a container within a loading area and positioned over a DUT footprint camera that identifies pin locations. An electrical testing module includes a probe workspace with multiple compressible electrical probes, each mounted and positioned via a probe positioning module. Probe cameras verify contact between each probe and the DUT pin. The robot lowers the DUT onto the probes for electrical engagement. The automated electrical probing system provides scalable, accurate, and socketless testing of packaged microelectronic devices.

### PRIORITY CLAIM

This application claims the benefit of U.S. Patent App. No. 63/655,933, filed on Jun. 4, 2024, titled “AUTOMATED ELECTRICAL PROBING MACHINE TO INTERFACE WITH HIGH VOLUMES AND VARIETIES OF PACKAGED MICROELECTRONICS,” the entire contents of which are incorporated herein by reference.

### BACKGROUND

In embodiments of the invention, a micro inspection platform (MIP) is provided for automated electrical and visual inspection of integrated circuit (IC) components. The platform may be configured as a turnkey system enabling high-throughput analysis in accordance with established standards including but not limited to AS6171. In embodiments, the platform may accommodate electronic components positioned in standard JEDEC trays or directly on an electrostatic discharge (ESD) mat and may be operable to detect, interface with, and test such components automatically.

In further embodiments, the platform may comprise a socketless interface that utilizes machine vision to align probes with device pins without the need for custom socket adapters, thereby supporting a wide range of IC package types. Electrical testing functionality may include power spectrum analysis (PSA), continuity testing, and pin-to-pin current-voltage (IV) curve tracing using one or more self-aligning probes. In some embodiments, the system may also support remote configuration and analysis, facilitating distributed or in-house test workflows.

In the field of microelectronics, testing, programming, and authentication of packaged components such as microprocessors and memory chips are critical steps before their integration onto printed circuit boards (PCBs). These components are manufactured in a wide range of package types such as Small Outline Integrated Circuit (SOIC), Quad Flat Package (QFP), and Ball Grid Array (BGA), each requiring precise electrical interfacing during pre-soldering operations.

Conventionally, such interfacing is achieved using mechanical socket adapters that mate with the physical geometry and pinout of each chip. However, off-the-shelf socket adapters are often unavailable for many package types, particularly for components with high pin counts or non-standard layouts. In such cases, custom socket adapters must be designed and manufactured, adding significant expense, time, and complexity. These sockets typically require additional test fixture circuitry to integrate with electrical testing equipment, further compounding development delays and costs.

Moreover, socket-based testing requires manual insertion of microelectronic components, which is labor-intensive, prone to human error, and potentially damaging to fragile chips. Manual probing systems suffer similar limitations requiring each probe to be aligned by hand to extremely small contact pads or pins, which is both time-consuming and impractical for high-volume testing environments.

Accordingly, there is a need for a more scalable, efficient, and cost-effective solution to electrically interface with a wide range of microelectronic package types and pin configurations. Such a solution should minimize the dependency on custom sockets and manual setup, reduce the likelihood of component damage, and allow for high-throughput testing with minimal operator intervention.

The present invention addresses these longstanding challenges by providing an automated electrical probing system that combines the flexibility of manual probe stations with the scalability and repeatability of robotic automation.

Thus, in view of the above, there is a long-felt need in the industry to address the aforementioned deficiencies and inadequacies.

Further limitations and disadvantages of conventional approaches will become apparent to one of skill in the art through the comparison of described systems with some aspects of the present disclosure, as outlined in the remainder of the present application and regarding the drawings.

### SUMMARY OF THE INVENTION

In one embodiment, an automated electrical probing system is provided to test a wide variety of packaged microelectronic devices using robotic positioning and computer vision. The system may include a robotic positioning mechanism configured to move a device under test (DUT) in x, y, and z directions and rotate it about a z-axis to achieve alignment with precision electrical probesos [symbol] .

In some embodiments, a robot end effector is coupled to the pick-and-place robot and configured to hold and release the DUT during handling. The end effector may comprise a suction nozzle to securely grip the DUT during transport and probing operations OBJ.

In another embodiment, a robot-mounted camera is configured to detect the position and orientation of the DUT within a defined loading area using computer vision OBJ. A DUT container may be used to hold multiple DUTs for sequential testing, and a DUT footprint camera may capture images or videos of the bottom side of the DUT, identifying pin locations using image recognition. This data may be used for calibration and alignment prior to electrical probing.

The system may further comprise an electrical testing module that includes a probe workspace configured to receive the DUT for electrical contact; a plurality of electrical probes, each compressible to maintain reliable contact; a probe mount for securing each probe in place; and a probe positioning module for aligning the probes in an x-y plane to match the pin layout of the DUT [symbol] .

In some embodiments, the probe positioning module includes actuators such as linear stages or robot arms to support probe movement and reconfiguration [symbol] . The probe workspace may define the mechanical limits within which the electrical probes operate and where DUT placement occurs.

Each probe may include a spring-loaded pogo pin to accommodate manufacturing variances in the DUT and ensure consistent contact bell. The probes may be dynamically configurable to support DUTs with different pin counts and layouts.

A set of probe cameras may be arranged to inspect the physical contact between each probe and the DUT. In some embodiments, these cameras are configured to capture images and video and may be used for visual analysis or calibration using machine learning or computer vision techniques [symbol] .

In an embodiment, the robot camera and DUT footprint camera may be operable to perform system calibration before each test cycle, enhancing accuracy and repeatability.

Each probe may be electrically connected to test and measurement equipment through a circuitry network, optionally including digital switches such as reed relays [symbol] . External channel connectors may route test signals from external equipment to the probes [symbol] .

In another embodiment, a simplified configuration of the system includes a pick-and-place robot, a vision system to detect DUT features and pin locations, and a control interface for operating movable electrical probes without custom sockets [symbol] .

In some embodiments, the system includes a microelectronics inspection platform (MIP) configured to perform power spectrum analysis (PSA) on DUTs. The MIP may include a processor configured to execute PSA via the probes and a machine learning module trained to identify anomalies or variations in PSA signatures. This approach allows for socketless, scalable defect detection using both electrical and visual data streams.

These embodiments provide a versatile, automated, and scalable platform for high-throughput testing of packaged microelectronics. By eliminating the need for custom sockets and manual alignment, the system improves test efficiency, accuracy, and adaptability across a range of component types and testing protocols.

### BRIEF DESCRIPTION OF THE DRAWINGS

The accompanying drawings illustrate the embodiment of apparatuses, devices, systems, methods, and other aspects of the disclosure. Any person with ordinary skills in the art will appreciate that the illustrated element boundaries (e.g., boxes, groups of boxes, or other shapes) in the figures represent an example of the boundaries. In some examples, one element may be designed as multiple elements, or multiple elements may be designed as one element. In some examples, an element shown as an internal component of one element may be implemented as an external component in another and vice versa. Furthermore, the elements may not be drawn to scale.

Various embodiments will hereinafter be described in accordance with the appended drawings, which are provided to illustrate, not limit, the scope, wherein similar designations denote similar elements, and in which:

FIG. 1 illustrates an environmental diagram of an automated electrical probing system, in accordance with at least one embodiment.

FIG. 2 illustrates a perspective view of key components of a micro inspection platform, in accordance with at least one embodiment.

FIG. 3 illustrates an exploded view of an electrical testing module, in accordance with at least one embodiment.

FIG. 4 illustrates a detailed, real-world view of a semiconductor device handling and probing station.

FIG. 5 illustrates an enclosed, production-ready version of the testing platform within a light-controlled environment.

### DETAILED DESCRIPTION

The present disclosure is best understood with reference to the detailed figures and description set forth herein. Various embodiments have been discussed with reference to the figures. However, those skilled in the art will readily appreciate that the detailed descriptions provided herein with respect to the figures are merely for explanatory purposes, as the methods and systems may extend beyond the described embodiments. For instance, the teachings presented and the needs of a particular application may yield multiple alternative and suitable approaches to implement the functionality of any detail described herein. Therefore, any approach may extend beyond certain implementation choices in the following embodiments.

References to “one embodiment,” “at least one embodiment,” “an embodiment,” “one example,” “an example,” “for example,” and so on indicate that the embodiment(s) or example(s) may include a particular feature, structure, characteristic, property, element, or limitation but that not every embodiment or example necessarily includes that particular feature, structure, characteristic, property, element, or limitation. Further, repeated use of the phrase “in an embodiment” does not necessarily refer to the same embodiment.

Methods of the present invention may be implemented by performing or completing manually, automatically, or a combination thereof, selected steps or tasks. The term “method” refers to manners, means, techniques, and procedures for accomplishing a given task including, but not limited to, those manners, means, techniques, and procedures either known to or readily developed from known manners, means, techniques, and procedures by practitioners of the art to which the invention belongs. The descriptions, examples, methods, and materials presented in the claims and the specification are not to be construed as limiting but rather as illustrative only. Those skilled in the art will envision many other possible variations within the scope of the technology described herein.

As used herein, and unless the context dictates otherwise, the term “configured to” or “coupled to” is intended to include both direct coupling (in which two elements that are coupled to each other contact each other) and indirect coupling (in which at least one additional element is located between the two elements). Therefore, the terms “configured to,” “configured with,” “coupled to” and “coupled with” are used synonymously. Within the context of this document terms “configured to,” “coupled to” and “coupled with” are also used euphemistically to mean “communicatively coupled with” over a network, where two or more devices can exchange data with each other over the network, possibly via one or more intermediary device.

It should be apparent to those skilled in the art that many more modifications besides those already described are possible without departing from the inventive concepts herein. The inventive subject matter, therefore, is not to be restricted except in the scope of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, utilized, or combined with other elements, components, or steps that are not expressly referenced.

The present invention provides an automated electrical probing system designed to interface with a wide variety of packaged microelectronic components in high-volume testing environments. The system retains the versatility of manual probe stations by supporting diverse package types and pin counts while overcoming their limitations through full automation of probe alignment and device handling. Unlike traditional testing setups that require costly and time-consuming custom mechanical sockets and supporting circuitry for each new package configuration, the disclosed system enables direct electrical interfacing with devices under test (DUTs) without the need for specialized adapters. This significantly reduces the complexity, cost, and lead time typically associated with microelectronic testing and programming.

The automated electrical probing system further enhances scalability by incorporating internet connectivity, allowing for remote operation, real-time monitoring, and cloud-based data storage and analysis. This eliminates the need for constant on-site presence of subject matter experts and enables distributed or automated workflows, making the solution particularly well-suited for modern, large-scale, and fast-paced production and R&D environments.

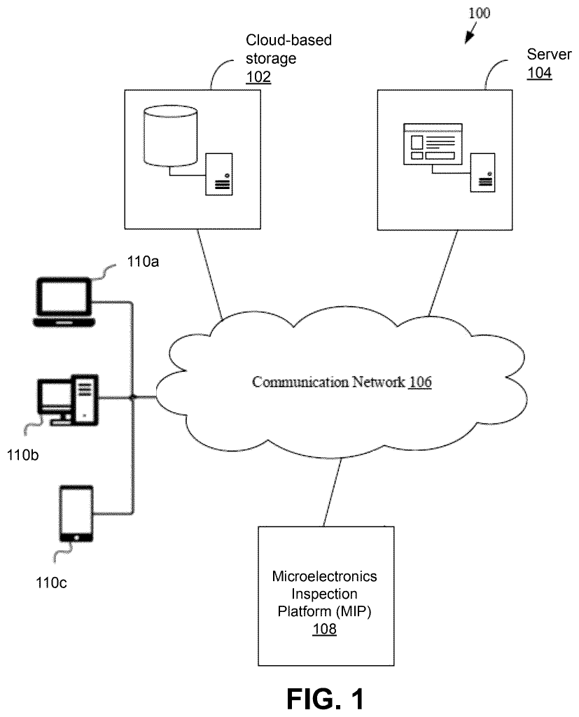

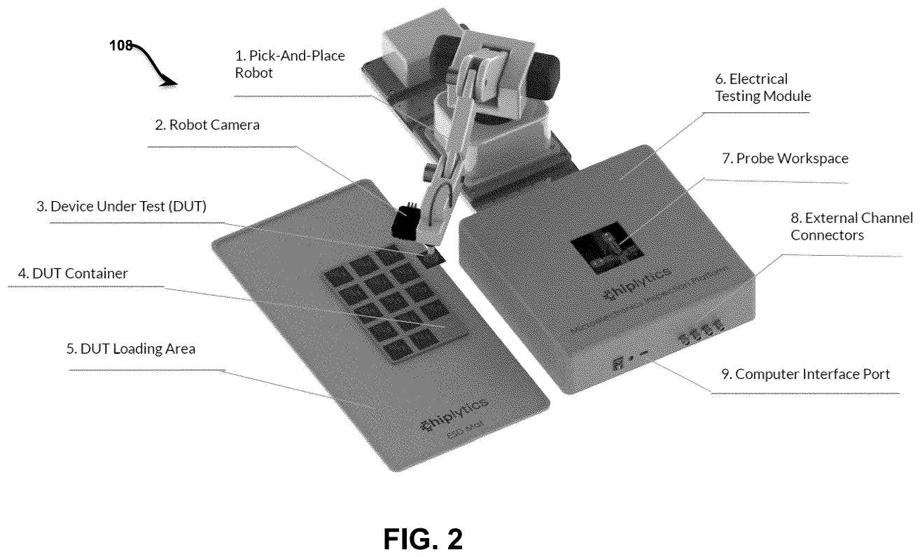

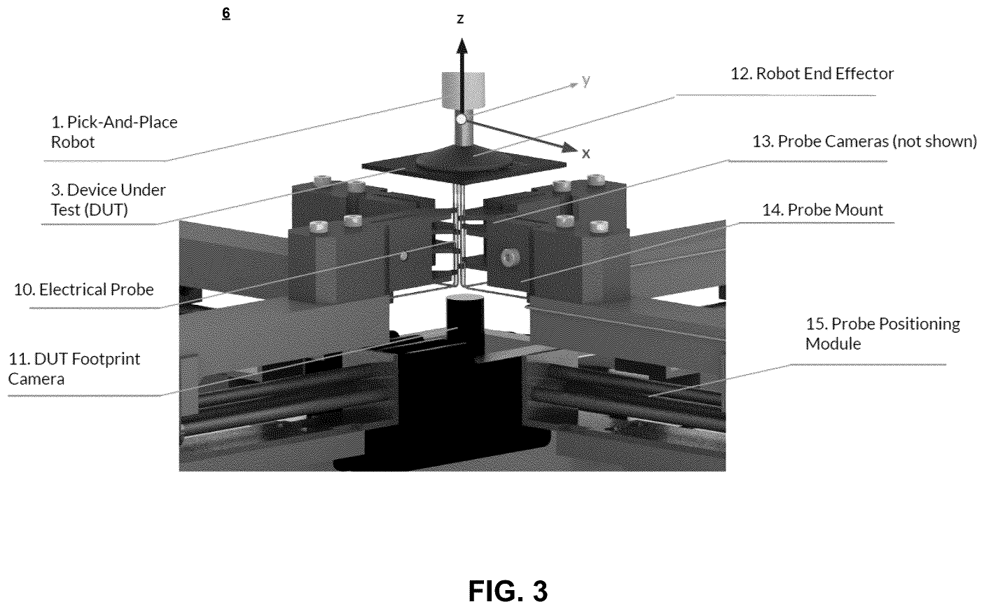

FIG. 1 illustrates an environmental diagram of an automated electrical probing system (100) for testing a plurality of microelectronic devices, in accordance with at least one embodiment. FIG. 1 is explained in conjunction with the elements of FIGS. 2-3. The automated electrical probing system (100) includes a pick-and-place robot (1), a robot end effector (12), a DUT (3), a robot camera (2), a DUT loading area (5), a DUT container (4), a DUT footprint camera (11), an electrical testing module (6), a set of external channel connectors (8), a computer interface port (9), an external computer (110), cloud-based storage (102), a server (104), and a Microelectronics Inspection Platform (MIP) (108). The pick-and-place robot (1) is configured to move a device under test (DUT) (3) in x, y, and z directions and rotate the DUT (3) about a z-axis. The robot end effector (12) is coupled to the pick-and-place robot (1) and configured to hold and release the DUT (3) during transport. The robot camera (2) is mounted on the pick-and-place robot (1), and the robot camera (2) is configured to detect a location and orientation of the DUT (3) in a DUT loading area (5) using computer vision. The DUT container (4) is positioned within the DUT loading area (5) and configured to receive a plurality of DUTs. The DUT footprint camera (11) is configured to capture images of the bottom side of the DUT (3) and a set of localized pins of the DUT (3) using computer vision. The electrical testing module (6) includes a probe workspace (7), a plurality of electrical probes (10), a probe mount (14), a probe positioning module (15), and a plurality of probe cameras (13).

The probe workspace (7) is configured to receive the DUT (3) for electrical contact. The electrical probes (10) are configured to contact with a set of designated pins of the DUT (3), each electrical probe (10) being compressible to ensure electrical connectivity. The probe mount (14) is configured to secure each electrical probe (10) in position. The probe positioning module (15) is configured to move each electrical probe (10) in an x-y plane to align with the set of designated pins of the DUT (3). The probe cameras (13) are configured to inspect the physical contact between each electrical probe (10) and the set of designated pins of the DUT (3). The pick-and-place robot (1) is operable to lower the DUT in the z-direction onto the positioned probes to make electrical contact with the set of designated pins.

The external channel connectors (8) are operable to route test signals from external measurement equipment to the electrical probes (10). The computer interface port (9) is configured to enable communication between the electrical testing module (6) and the external computer (110a, 110b, and 110c) collectively referred to as the external computer (110). In an embodiment, the external computer 110 is a device that is used by a user to access the Microelectronics Inspection Platform (MIP) and the electrical testing module. Examples of the external computer (110) may include but are not limited to, a personal computer, a laptop, a personal digital assistant (PDA), a mobile device, a tablet, or any other computing device.

In an embodiment, the external computer (110) is configured to operate the automated electrical probing system (100) remotely over the Internet and log test results to the cloud-based storage (102). In an embodiment, cloud-based storage (102) may refer to a computing device that may be configured to store electrical test and measurement data. In an embodiment, the cloud-based storage (102) is a database that may include a special-purpose operating system specifically configured to perform one or more database operations on data related to the first unique client identifier, the second unique client identifier, and the third unique client identifier. Examples of database operations may include, but are not limited to, select, insert, update, and delete.

The cloud-based storage (102) may be configured to transmit the data to the server (104) for data processing, via the communication network (106). In an embodiment, the database (102) may be configured to transmit the data to server 104 at one or more locations for showcasing the electrical test and measurement data.

A person with ordinary skills in the art will understand that the scope of the disclosure is not limited to the cloud-based storage (102) as a separate entity. In an embodiment, the functionalities of the cloud-based storage (102) can be integrated into the server (104).

In an embodiment, the server (104) may refer to a computing device or a software framework hosting an application or a software service. In an embodiment, the server (104) may be implemented to execute procedures such as, but not limited to, programs, routines, smart contracts, or scripts stored in one or more memories for supporting the hosted application or the software service. In an embodiment, the hosted application or the software service may be configured to perform one or more predetermined operations. The server (104) may be realized through various types of web or application servers such as, but are not limited to, a Python web server, a NodeJS web server, a Java application server, aNET framework application server, a Base4 application server, a PHP framework application server, or any other application server framework. In an embodiment, server 104 may be realized through various types of mobile application servers such as, but not limited to, Backendless, Firebase, AWS (Amazon Web Services), and Microsoft Azure. In an embodiment, the software service may be configured to run offline without the presence of a network connection.

A person having ordinary skill in the art will appreciate that the scope of the disclosure is not limited to realizing the server (104), and the external computer (110) as separate entities.

In one embodiment, the communication network (106) may correspond to a communication medium through which the database (102), the server (104), the micro inspection platform (108), and the external computer (110) may communicate with each other. Such communication may be performed, in accordance with various wired and wireless communication protocols. Examples of such wired and wireless communication protocols include but are not limited to, transmission control protocol and internet protocol (TCP/IP), user datagram protocol (UDP), hypertext transfer protocol (HTTP), file transfer protocol (FTP), ZigBee, EDGE, infrared (IR), IEEE 802.11, 802.16, 2G, 3G, 4G cellular communication protocols, and/or Bluetooth (BT) communication protocols. The communication network (106) may include but is not limited to, the Internet, a cloud network, a Wireless Fidelity (Wi-Fi) network, a wireless local area network (WLAN), a local area network (LAN), a telephone line (POTS), and/or a metropolitan area network (MAN).

FIG. 2 illustrates a perspective view of key components of a microelectronics inspection platform (MIP) (108), in accordance with at least one embodiment. FIG. 2 is explained in conjunction with the elements of FIG. 1. The probe workspace (7) defines the range of motion of the electrical probes (10) and where the DUT (3) is positioned to be probed. In an embodiment, each electrical probe (10) comprises a spring-loaded pogo pin configured to ensure adequate electrical contact and compensate for positional tolerances in the pins of the DUT (3).

FIG. 3 illustrates an exploded view of an electrical testing module, in accordance with at least one embodiment. FIG. 2 is explained in conjunction with the elements of FIG. 1-FIG. 2. The DUT footprint camera (11) is further configured to capture video recordings and perform system calibration using computer vision techniques. In an embodiment, the robot end effector (12) comprises a suction nozzle configured to securely hold the DUT (3) during transport and placement onto the probe workspace (7). In an embodiment, the probe cameras (13) are further configured to capture images and videos of the DUT (3) and to perform visual analysis and calibration using computer vision and machine learning. In an embodiment, the probe positioning module (15) comprises one or more actuators selected from linear stages and robot arms configured to move the electrical probes (10) in the x-y plane. In an embodiment, the robot camera (2) and the DUT footprint camera (11) are operable to perform calibration of the system before electrical probing of the DUT (3). In an embodiment, the electrical probes (10) are dynamically configurable to accommodate varying pin counts and layouts of different DUTs (3). In an embodiment, each electrical probe (10) is electrically connected to the electrical test and measurement equipment through a circuitry network comprising digital switches, including reed relays.

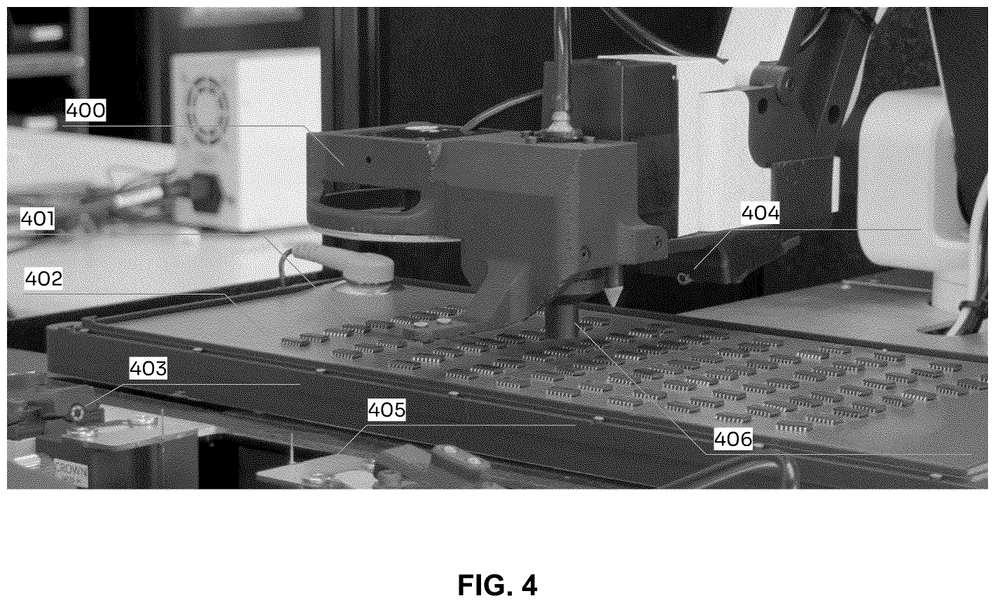

FIG. 4 illustrates a semiconductor testing and handling station. A DUT packaging camera (400) is positioned above the work area to monitor device placement and packaging. Positioned below is a device under test (DUT) (401), secured during evaluation. The DUT is supported by a removable ESD tray (402) designed to prevent electrostatic discharge damage.

Flanking the station are two side microscopes (403, 404) that provide lateral high-magnification imaging. Beneath the DUT, self-aligning probes (405) contact the device for electrical testing. Nearby, an ESD-safe suction nozzle (406) is used to handle components without introducing static or mechanical stress.

This arrangement enables precise alignment, inspection, and non-destructive testing of sensitive semiconductor components.

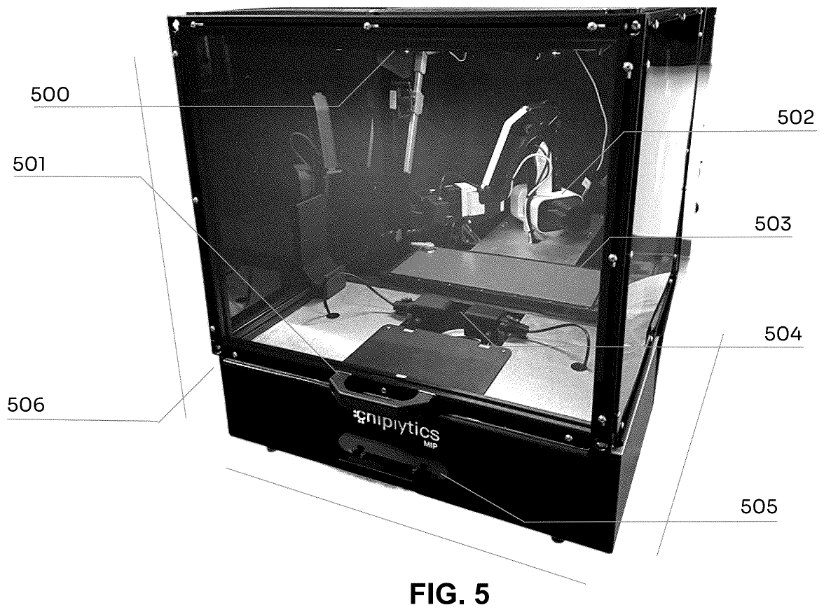

FIG. 5 illustrates a compact semiconductor test station enclosed within a protective lightbox. An overhead camera with illumination and status LEDs (500) is mounted at the top of the unit to capture visual data from above. The structure is enclosed by a hinged lightbox (501) that helps maintain consistent lighting conditions and reduce glare or interference.

A robot arm (502) is positioned inside the enclosure for automated handling of components. Below it, a removable ESD tray (503) provides a static-safe surface for holding a device under test (DUT). Adjacent to the tray is a self-aligning probe system with DUT footprint camera (504), used for making contact with the DUT and aligning based on its layout.

A chip catcher tray (505) is located at the bottom front of the unit to collect dislodged or ejected components. On the left side of the unit, a power input panel (506) includes a 12V input, USB 3.0 type-B data port, grounding jack, and power switch (not shown).

In an embodiment, the automated electrical probing system (100) may include a processor, and memory, wherein the processor and the memory may be coupled to the external computer (110) or Microelectronics Inspection Platform (MIP). In an embodiment, the processor is configured to: pick up each DUT from the DUT loading area using the pick-and-place robot; capture the footprint of the DUT via the DUT footprint camera to determine the location of pins; move each electrical probe to align with the corresponding pins using the probe positioning module; press the DUT against the electrical probes to establish contact; execute electrical tests or operations using embedded or external testing equipment; and return the DUT to the DUT loading area after testing.

In some embodiments, the present system may include modular components such as swappable probe heads for interfacing with different pin types (e.g., ball, flat, or through-hole leads), interchangeable end-effectors tailored to various chip form factors, and extensible test and measurement circuits. Supporting software tools may also be provided to facilitate test execution, calibration, and results analysis.

In some embodiments, the automated electrical probing system (100) is configured to interface with various package types and pin counts of microelectronic components. In one of the implementations, the pick-and-place robot (1) is configured to pick up microelectronic components, position them along the x, y, and z axes, and rotate them about the z-axis. The pick-and-place robot (1) is equipped with a robot end effector (12), such as a suction nozzle, which securely holds and releases each DUT (3) during transport and probing operations. Attached to the pick-and-place robot (1) and/or fixed in space above is a robot camera (2) configured to detect the location and orientation of the DUT (3) within a defined DUT loading area (5) using computer vision techniques. This camera may also capture images and videos, assist in calibration, and perform visual inspection using AI-based models.

The DUT (3) is initially positioned within a DUT container (4), which may be an original chip tray, such as a JEDEC tray, or any custom or standardized container. Alternatively, DUTs (3) may be freely placed in the DUT Loading Area (5) and localized via the robot camera (2).

The DUT (3) is transferred by the robot to the DUT footprint camera (11), which captures high-resolution images of the DUT's bottom surface. This camera utilizes computer vision to identify the location of each pin or contact of the DUT (3) and assists in calibrating the system. The DUT (3) is then moved into the probe workspace (7) located within the electrical testing module (6). This module includes electrical probes (10), each of which is compressible, for example, using spring-loaded pogo pins, to compensate for minor misalignments and ensure electrical contact. Each probe is mounted onto a Probe Mount (14) and is individually movable in the x/y plane by a dedicated Probe Positioning Module (15). These positioning modules may include actuators such as linear stages or robotic arms to precisely align each Electrical Probe (10) with a corresponding DUT pin.

Further, the probe cameras (13) are oriented to inspect and verify the physical alignment and contact between the probes and the DUT (3) and may be used for image capture, calibration, and pin-level analysis.

The pick-and-place robot (1) lowers the DUT (3) along the z-axis to establish contact between the DUT pins and the aligned Electrical Probes (10). After contact is made, the electrical testing module (6) initiates a test sequence using built-in test circuitry or external instrumentation routed via external channel connectors (8). The computer interface port (9) allows an external computer to control the test sequence, collect data, and interface with user software.

Once testing is complete, the DUT (3) is released from the probes and returned to its original location in the DUT loading area (5) using the pick-and-place robot (1). The cycle is repeated for each DUT present.

The present disclosure further describes the assembly and usage of the present automated electrical probing system (100). To begin with, the pick-and-place robot (1) is configured with degrees of freedom for translational and rotational movement. The robot camera (2) is mounted near the end-effector to visually identify DUT locations. A second upward-facing camera serves as the DUT footprint camera (11). Each probe positioning system includes robotic mechanisms capable of 2D movement, such as linear actuators, onto which probe mounts (14) are affixed. Probes are spring-loaded and secured between circuit boards for vertical alignment. Each probe is electrically routed to measurement instrumentation using appropriate switches, such as reed relays. Digital microscopes serve as probe cameras (13) to monitor connectivity and alignment. Custom software is executed on an external computer to coordinate robotic motion, probe alignment, testing, and camera functions. Internet connectivity is optional but enables cloud data storage, remote diagnostics, and access to part databases.

Calibration routines use fiducial markers, test pin locations, or unique DUT patterns to correct mechanical or optical misalignments. Additional calibration and drift correction may be performed regularly during operation. Lighting systems, thermal sensors, and fans can be incorporated for environmental stability.

The number of probes may vary depending on the testing needs. Probes may be of various types, including elastomeric or rigid contact styles. A universal fine-pitch probe array could eliminate the need for movable probes. The system may include programmable routing of test equipment outputs such as waveform generators or power supplies to specific probes.

Further, the present invention also contemplates modular end-effectors for handling various DUT shapes, and swappable probe heads for different pin interfaces (ball, flat, or through-hole). Tape-and-reel designs and custom reel tags could be used for continuous testing workflows and post-test marking.

The present disclosure further describes the method of use of the present automated electrical probing system (100). To operate the system, the user initiates software on an external computer connected to the system via the computer interface port (9). Upon initial setup or power-up, the user launches calibration routines. The DUT part number is entered, and test specifications are retrieved either from an online database, internal library, or user input.

The user configures the testing protocol by selecting pins to be probed and defining measurement parameters. Devices are loaded into the DUT Loading Area (5), either in trays or freely placed. The robot automatically identifies each DUT (3), aligns it, presses it onto probes, conducts testing, and returns the DUT. This process is repeated for all loaded devices.

Analysis tools provided in the software or via third-party platforms allow result review. Remote expert support may be used via an internet connection. The system is primarily intended for use before PCB assembly but may be adapted for additional applications such as programming, post-rework inspection, or medical device probing.

The present disclosure further describes the applications and variations of the present automated electrical probing system (100). The system may be applied beyond microelectronics to any domain requiring precision probe alignment with miniature components. Modular hardware and software elements support future extensibility, such as support for larger package types, additional probes, or advanced machine learning analytics.

Thus, the present system provides a robust, flexible, and cost-effective solution for high-volume inspection and testing of microelectronic components to improve upon existing methods in terms of scalability, speed, and reliability.

No language in the specification should be construed as indicating any non-claimed element as essential to the practice of the invention. It will be apparent to those skilled in the art that various modifications and variations can be made to the present invention without departing from the scope of the invention. There is no intention to limit the invention to the specific form or forms enclosed. On the contrary, the intention is to cover all modifications, alternative constructions, and equivalents falling within the scope of the invention, as defined in the appended claims. Thus, it is intended that the present invention cover the modifications and variations of this invention, provided they are within the scope of the appended claims and their equivalents.

We claim:

1. An automated electrical probing system, comprising:
a robotic positioning system configured to move a device under test (DUT) in x, y, and z directions and rotate the DUT about a z-axis;
a robot end effector coupled to the pick-and-place robot and configured to hold and release the DUT during transport;
a robot camera mounted on the pick-and-place robot, the robot camera configured to detect a location and orientation of the DUT in a DUT loading area using computer vision;
a DUT container positioned within the DUT loading area and configured to receive a plurality of DUTs;
a DUT footprint camera configured to capture images of a bottom side of the DUT and a set of localized pins of the DUT using computer vision;
an electrical testing module, comprising:
a probe workspace configured to receive the DUT for electrical contact;
a plurality of electrical probes configured to contact a set of designated pins of the DUT, each electrical probe being compressible to ensure electrical connectivity;
a probe mount configured to secure each electrical probe in position;
a probe positioning module configured to move each electrical probe in an x-y plane to align with the set of designated pins of the DUT; and
a plurality of probe cameras configured to inspect the physical contact between each electrical probe and the set of designated pins of the DUT, wherein the pick-and-place robot is operable to lower the DUT in the z-direction onto the positioned probes to make electrical contact with the set of designated pins; and
a set of external channel connectors operable to route test signals from an electrical test and measurement equipment to the electrical probes.

2. The automated electrical probing system of claim 1, wherein the probe workspace defines a range of motion of the electrical probes and where the DUT is positioned to be probed.

3. The automated electrical probing system of claim 1, wherein each electrical probe comprises a spring-loaded pogo pin configured to ensure adequate electrical contact and compensate for positional tolerances in the pins of the DUT.

4. The automated electrical probing system of claim 1, wherein the DUT footprint camera is further configured to capture video recordings and perform system calibration using computer vision techniques.

5. The automated electrical probing system of claim 1, wherein the robot end effector comprises a suction nozzle configured to securely hold the DUT during transport and placement onto the probe workspace.

6. The automated electrical probing system of claim 1, wherein the probe cameras are further configured to capture images and videos of the DUT and to perform visual analysis and calibration using computer vision and machine learning.

7. The automated electrical probing system of claim 1, wherein the probe positioning module (15) comprises one or more actuators selected from linear stages and robot arms configured to move the electrical probes in the x-y plane.

8. The automated electrical probing system of claim 1, wherein the robot camera and DUT footprint camera are operable to perform calibration of the system before electrical probing of the DUT.

9. The automated electrical probing system of claim 1, wherein the plurality of electrical probes are dynamically configurable to accommodate varying pin counts and layouts of different DUTs.

10. The automated electrical probing system of claim 1, wherein each electrical probe is electrically connected to the electrical test and measurement equipment through a circuitry network.

11. An automated probing system for testing microelectronic devices, comprising:
a pick-and-place robot configured to move a device under test (DUT);
an end effector coupled to the robot for handling the DUT;
a vision system configured to detect DUT features and pin locations;
a probing module comprising movable electrical probes and a workspace for receiving the DUT; and
a control interface configured to operate the robot and probes to electrically contact designated pins of the DUT without custom sockets.

12. An automated microelectronics testing system, comprising:
a microelectronics inspection platform (MIP) comprising
a pick-and-place robot configured to transport a plurality of packaged devices under test (DUTs);
a DUT footprint camera configured to capture images of pin layouts of the DUTs using computer vision;
a probe workspace comprising a plurality of compressible electrical probes, each configured to contact designated pins of the DUTs;
a probe positioning module operable to align the electrical probes in an x-y plane based on the pin layout;
a processor configured to execute power spectrum analysis (PSA) on each DUT via the electrical probes; and
a machine learning module configured to analyze PSA results using features extracted from visual and electrical data collected during testing,
wherein the system is configured to perform PSA tests on the DUTs without requiring custom sockets, and
wherein the machine learning module is trained to detect anomalies or variations in PSA signatures across a batch of DUTs to identify potential differences.
